(19) United States
(12) Patent Application Publication
(10) Pub. No.: US 2026/0047413 A1
(43) Pub. Date: Feb. 12, 2026

(54) SEMICONDUCTOR DEVICE WITH SELF-ALIGNED CONTACT VIA AND METHOD FOR MANUFACTURING THE SAME

(71) Applicant: TAIWAN SEMICONDUCTOR MANUFACTURING COMPANY, LTD., Hsinchu (TW)

(72) Inventors: Chan-Yu Liao, Hsinchu (TW); Li-Ling SU, Hsinchu (TW); Yung-Chih WANG, Hsinchu (TW); Chuan-Pu CHOU, Hsinchu (TW); Yu-Chieh LIAO, Hsinchu (TW); Chia-Wei SU, Hsinchu (TW); Kun-Yen LIAO, Hsinchu (TW); Wan-Hua HO, Hsinchu (TW); Yung-Hsu WU, Hsinchu (TW); Hsin-Ping CHEN, Hsinchu (TW)

(73) Assignee: TAIWAN SEMICONDUCTOR MANUFACTURING COMPANY, LTD., Hsinchu (TW)

(21) Appl. No.: 18/798,031

(22) Filed: Aug. 8, 2024

(51) Int. Cl. H01L 21/768

(52) U.S. Cl. CPC H01L 21/76897; H01L 21/7682

(57) ABSTRACT

A method for manufacturing a semiconductor device includes: forming metal lines on a substrate; forming first dielectric portions on the metal lines, respectively; forming first mask portions on the first dielectric portions, respectively; forming second dielectric portions on the substrate; selectively forming second mask portions on the second dielectric portions, respectively; removing one of the first mask portions and a corresponding one of the first dielectric portions, so as to form an opening that exposes a corresponding one of the metal lines; forming a contact via material layer to fill the opening; and removing a portion of the contact via material layer, remaining ones of the first mask portions and the second mask portions, so as to form a contact via that is disposed on and electrically connected to the corresponding one of the metal lines.

### BACKGROUND

Integrated circuit (IC) chips are important components in, for example, but not limited to, consumer 's electrical products, such as a mobile phone, a central processing unit (CPU) in a computer, etc. In order to increase the functional density (i.e., the number of semiconductor devices per chip area) and the economic benefit of an IC chip, a continual reduction in minimum feature size s of the IC chip is required. However, some issues, e.g., a lithography overlay shift, may occur with the scaling down of the feature sizes of the IC chip (e.g., contact vias or metal lines of an interconnect structure in the IC chip), which may adversely affect production yield and reliability of the IC chip.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 13 are schematic views illustrating some intermediate stages of the method as depicted in FIG. 1 in accordance with some embodiments.

FIG. 14 is a schematic view illustrating a semiconductor device in accordance with some embodiments.

FIGS. 15 and 16 are schematic views illustrating intermediate stages of a method for manufacturing the semiconductor device shown in FIG. 14 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain region(s)” may refer to a source or a drain, individually or collectively dependent upon the context.

Scaling down pitches of features of an integrated circuit (IC) chip is a trend in the semiconductor industry; however, some issues may occur thereby. For example, in a process for manufacturing an interconnect structure of an IC chip, during formation of a contact via on a metal line, a lithography overlay shift may occur, which may cause a mismatch (e.g., in position or size) between the contact via and the metal line, and which may further cause a reduced distance between the contact via and another metal line that is adjacent to the metal line on which the contact via is disposed. The reduced distance between the contact via and the another metal line may result in formation of a current leakage therebetween and degradation in a time-dependent dielectric breakdown (TDDB), thereby adversely affecting production yield and reliability of the IC chip. For another example, as an IC chip shrinks, a size of each of metal lines in an interconnect structure of the IC chip becomes smaller, and a distance between two adjacent ones of the metal lines is reduced, which may cause an undesirable increase in a capacitance between the metal lines, and which may further adversely affect performance of the IC chip. For yet another example, a reduction in a size of the contact via in the interconnect structure of the IC chip may increase difficulty in formation of the contact via, which may also adversely affect the production yield and the reliability of the IC chip.

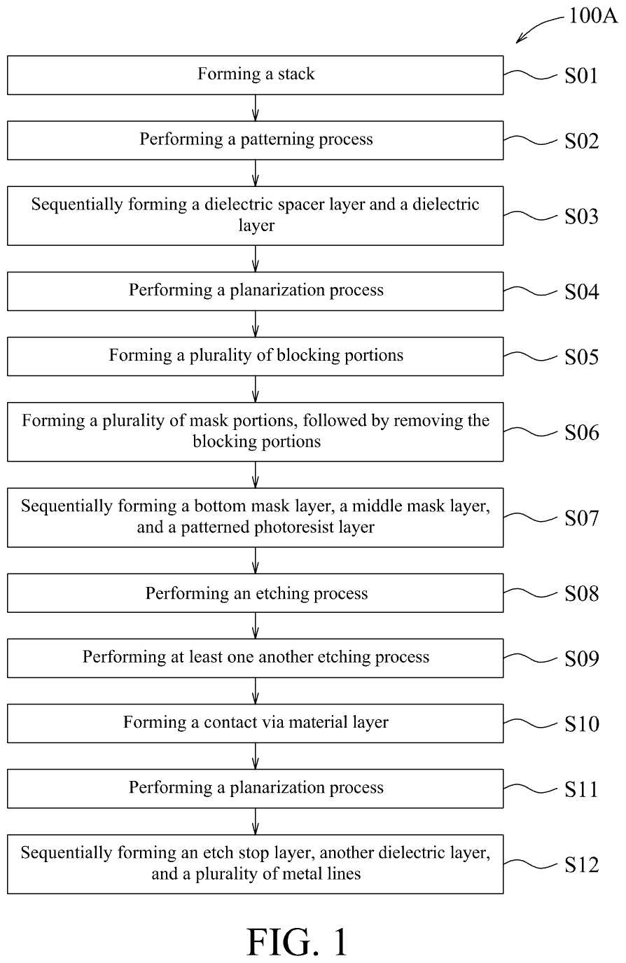

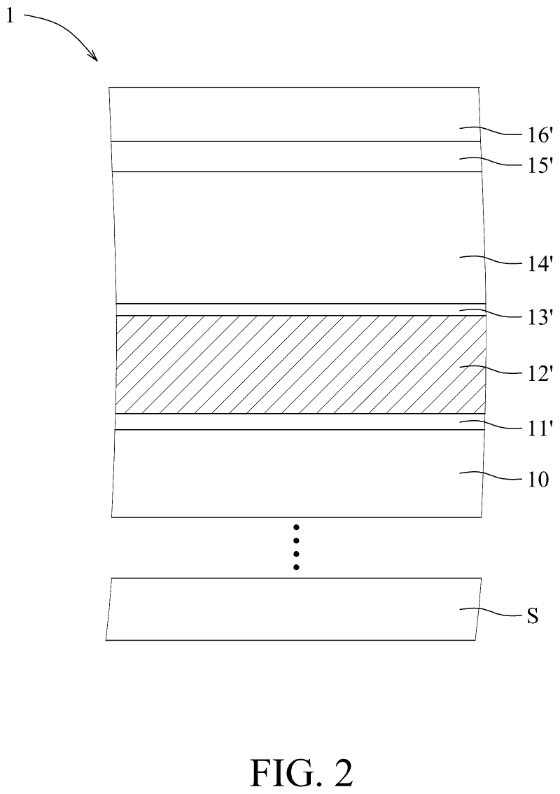

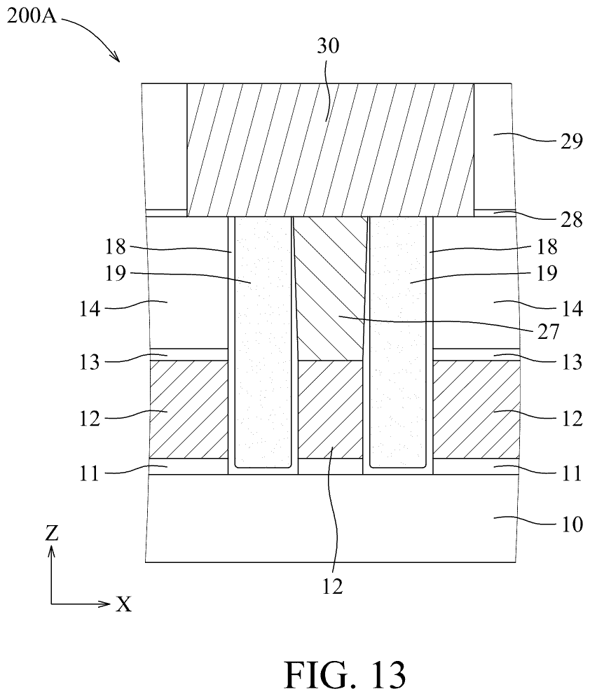

The present disclosure is directed to a semiconductor device and a method for manufacturing the same. FIG. 1 is a flow diagram illustrating a method 100A for manufacturing a semiconductor device 200A shown in FIG. 13 in accordance with some embodiments. FIGS. 2 to 12C illustrate schematic views of some intermediate stages of the method 100A. Some portions may be omitted in FIGS. 2 to 12C for the sake of brevity. Additional steps can be provided before, after or during implementation of the method 100A, and some of the steps described herein may be replaced by other steps or be eliminated.

Referring to FIG. 1 and the example illustrated in FIG. 2, the method 100A begins at step S01, where a stack 1 is formed over a substrate(S) (shown only in FIG. 2). In some embodiments, the substrate(S) may be a semiconductor substrate, for example, but not limited to, an elemental semiconductor (e.g., silicon or germanium) or a compound semiconductor (e.g., silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, gallium indium arsenide phosphide, or the like). The stack 1 includes an interconnect structure 10, a glue layer 11′, a metal line material layer 12′, an etch stop layer 13′, a dielectric layer 14′, a dielectric layer 15′, and a mask layer 16′.

In some embodiments, the interconnect structure 10 may be a middle-end-of-line (MEOL) interconnect structure, which includes a contact via electrically connected to a component (e.g., a source/drain region or a metal gate) of a transistor of a front-end-of-line (FEOL) structure of the IC chip. In some alternative embodiments, the interconnect structure 10 may be a back-end-of-line (BEOL) interconnect structure of the IC chip and includes a contact via disposed in a dielectric layer.

The glue layer 11′ is disposed on the interconnect structure 10. In some embodiments, the glue layer 11′ may include, for example, but not limited to, metal (for example, titanium, tantalum, or the like), metal nitride (for example, titanium nitride, tantalum nitride, or the like), or a combination thereof. Other suitable materials for forming the glue layer 11′ are within the contemplated scope of the present disclosure. In some embodiments, the glue layer 11′ may be formed by a suitable deposition process, for example, but not limited to, chemical vapor deposition (CVD), physical vapor deposition (PVD), or atomic layer deposition (ALD). Other suitable deposition processes for forming the glue layer 11′ are within the contemplated scope of the present disclosure. The glue layer 11′ may be used to increase adhesion of the metal line material layer 12′ to the interconnect structure 10, and/or may serve as an etch stop layer in a subsequent etching process.

The metal line material layer 12′ is disposed on the glue layer 11′ opposite to the interconnect structure 10. In some embodiments, the metal line material layer 12′ may be made of a conductive material, for example, but not limited to, copper, molybdenum, ruthenium, cobalt, tantalum, niobium, aluminum, or combinations thereof. Other suitable conductive materials for forming the metal line material layer 12′ are within the contemplated scope of the present disclosure. In some embodiments, the metal line material layer 12′ may have a thickness ranging from about 100 Å to about 5000 Å. If the thickness of the metal line material layer 12′ is less than about 100 Å, the resistance of conductive interconnects (for example, metal lines) formed thereby may be increased.

The etch stop layer 13′ is disposed on the metal line material layer 12′ opposite to the glue layer 11′. In some embodiments, the etch stop layer 13′ may be made of a non-conductive material, for example, but not limited to, silicon oxide, silicon nitride, silicon carbide, silicon carbonitride, silicon oxycarbide, aluminum oxide, aluminum nitride, aluminum oxynitride, or combinations thereof. Other suitable non-conductive materials for forming the etch stop layer 13′ are within the contemplated scope of the present disclosure. In some embodiments, the etch stop layer 13′ may be formed by a suitable deposition process, for example, but not limited to, CVD, PVD, or ALD. Other suitable deposition processes for forming the etch stop layer 13′ are within the contemplated scope of the present disclosure.

The dielectric layer 14′ is disposed on the etch stop layer 13′ opposite to the metal line material layer 12′. In some embodiments, the dielectric layer 14′ may be made of a low-dielectric constant (k) material, for example, but not limited to, hydrogenated silicon carbide, silicon oxide, silicon nitride, silicon carbide, silicon carbonitride, silicon oxycarbide, or combinations thereof. Other suitable low-k materials for forming the dielectric layer 14′ are within the contemplated scope of the present disclosure. In some embodiments, the dielectric layer 14′ may be formed by a suitable deposition process, for example, but not limited to, CVD or PVD. Other suitable deposition processes for forming the dielectric layer 14′ are within the contemplated scope of the present disclosure. In some embodiments, the dielectric layer 14′ may be formed as a single layer structure or a multilayered structure. In some embodiments, the dielectric layer 14′ may be formed as a porous structure.

The dielectric layer 15′ is disposed on the dielectric layer 14′ opposite to the etch stop layer 13′. In some embodiments, the dielectric layer 15′ may include silicon oxide. Other suitable materials for forming the dielectric layer 15′ are within the contemplated scope of the present disclosure. In some embodiments, the dielectric layer 15′ may be formed by a suitable deposition process, for example, but not limited to, CVD or PVD. Other suitable deposition processes for forming the dielectric layer 15′ are within the contemplated scope of the present disclosure. In some embodiments, the dielectric layer 15′ and the dielectric layer 14′ may be made of different materials.

The mask layer 16′ is disposed on the dielectric layer 15′ opposite to the dielectric layer 14′. In some embodiments, the mask layer 16′ may include a metallic material, for example, but not limited to, metal nitride (e.g., titanium nitride or the like). Other suitable materials for forming the mask layer 16′ are within the contemplated scope of the present disclosure.

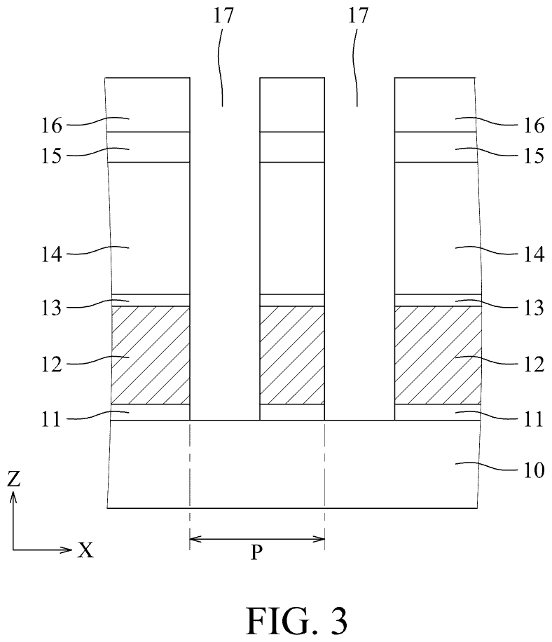

Referring to FIG. 1 and the example illustrated in FIG. 3, the method 100A then proceeds to step S02, where a patterning process is performed to pattern the stack 1, so as to form a plurality of trenches 17. In some embodiments, the patterning process may be a photolithography process, which includes at least one etching process. In some embodiments, the photolithography process may include, for example, but not limited to, coating a photoresist (not shown) on the mask layer 16′, soft-baking the photoresist, exposing the photoresist through a photomask (not shown), post-exposure baking the photoresist, and developing the photoresist, followed by hard-baking the photoresist so as to form a patterned photoresist on the mask layer 16′. In the at least one etching process, the mask layer 16′, the dielectric layer 15′, the dielectric layer 14′, the etch stop layer 13′, the metal line material layer 12′, and the glue layer 11′ may be etched by a suitable etching process (for example, but not limited to, dry etching, wet etching, a combination thereof, or other suitable etching processes) using the patterned photoresist as a patterned mask. The patterned photoresist may be removed by, for example, but not limited to, an ashing process or other suitable removal processes after the at least one etching process. Other suitable patterning processes are within the contemplated scope of the present disclosure. In some embodiments, the trenches 17 are spaced apart from one another in an X direction parallel to an upper surface of the interconnect structure 10. In some embodiments, each of the trenches 17 penetrates the mask layer 16′, the dielectric layer 15′, the dielectric layer 14′, the etch stop layer 13′, the metal line material layer 12′ and the glue layer 11′ in a Z direction transverse to the X direction, and terminates at the upper surface of the interconnect structure 10. After this step, the mask layer 16′ is formed into a plurality of mask portions 16; the dielectric layer 15′ is formed into a plurality of dielectric portions 15; the dielectric layer 14′ is formed into a plurality of dielectric portions 14; the etch stop layer 13′ is formed into a plurality of etch stop layer portions 13; the metal line material layer 12′ is formed into a plurality of metal lines 12; and the glue layer 11′ is formed into a plurality of glue layer portions 11. In some embodiments, a width of each of the metal lines 12 and a distance between the each of the metal lines 12 and an immediately adjacent one of the metal lines 12 may be collectively defined as a pitch (p). In some embodiments, the pitch (p) may be not greater than about 200 nm.

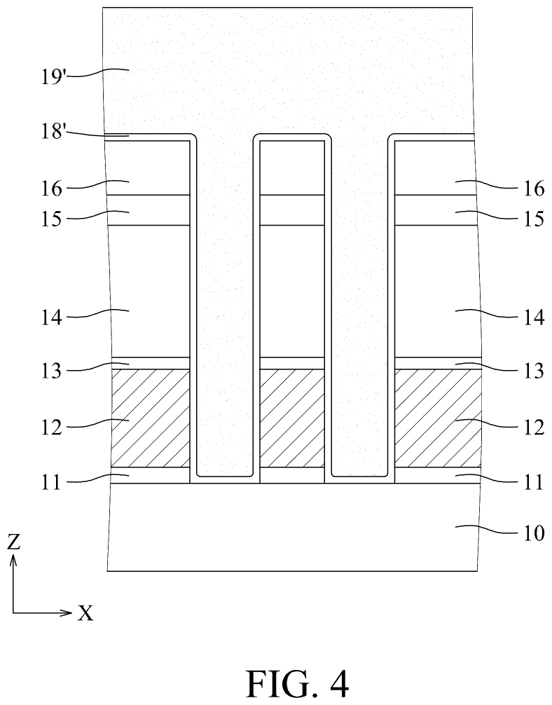

Referring to FIG. 1 and the example illustrated in FIG. 4, the method 100A then proceeds to step S03, where a dielectric spacer layer 18′ and a dielectric layer 19′ are sequentially formed on the structure shown in FIG. 3. Step S03 includes sub-steps (i) and (ii).

In sub-step (i), the dielectric spacer layer 18′ is conformally formed on the structure shown in FIG. 3. The material and the process for forming the dielectric spacer layer 18′ may be the same as or similar to those for forming the dielectric layer 15′, and thus details thereof are omitted for the sake of brevity.

In sub-step (ii), the dielectric layer 19′ is formed on the dielectric spacer layer 18′ and fills the trenches 17 (see FIG. 3). The material and the process for forming the dielectric layer 19′ may be the same as or similar to those for forming the dielectric layer 14′, and thus details thereof are omitted for the sake of brevity. In some embodiments, the dielectric layer 19′ and the dielectric layer 14′ may be made of the same material. In some alternative embodiments, the dielectric layer 19′ and the dielectric layer 14′ may be made of different materials. In some alternative embodiments, the dielectric layer 19′ and the dielectric spacer layer 18′ may be made of different materials.

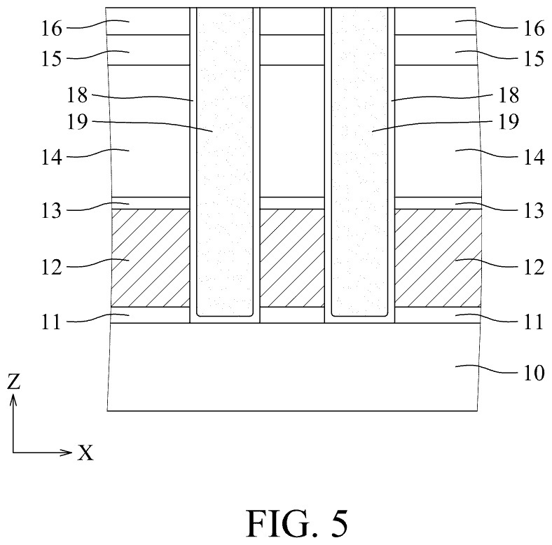

Referring to FIG. 1 and the example illustrated in FIG. 5, the method 100A then proceeds to step S04, where a portion of the dielectric layer 19′, portions of the dielectric spacer layer 18′, and a portion of each of the mask portions 16 are removed. Step S04 may be performed by a suitable planarization process, for example, but not limited to, chemical mechanical polishing (CMP) process. Other suitable planarization processes are within the contemplated scope of the present disclosure. After this step, the dielectric spacer layer 18′ is formed into a plurality of dielectric spacers 18 and the dielectric layer 19′ is formed into a plurality of dielectric portions 19, where a lateral surface and a bottom surface of each of the dielectric portions 19 are covered by a corresponding one of the dielectric spacers 18.

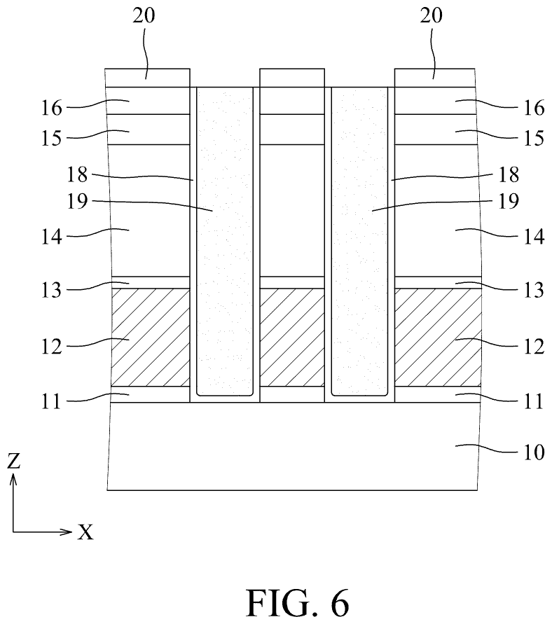

Referring to FIG. 1 and the example illustrated in FIG. 6, the method 100A then proceeds to step S05, where a plurality of blocking portions 20 are formed and adsorbed on the mask portions 16, respectively. In some embodiments, the blocking portions 20 may be made from a self-assembled monolayer (SAM) material. In some embodiments, the SAM material may include, for example, but not limited to, an organic molecule or polymer (e.g., benzotriazole (BTA), phosphonic acid, octadecylphosphonic acid (ODPA), organosulfur compound, thiol (e.g., dodecanethiol, alkanethiol, or the like), or the like ). Other suitable materials for forming the blocking portions 20 are within the contemplated scope of the present disclosure. In some embodiments, the blocking portions 20 may be formed by a suitable technique, for example, but not limited to, spin-on coating. Other suitable techniques for forming the blocking portions 20 are within the contemplated scope of the present disclosure.

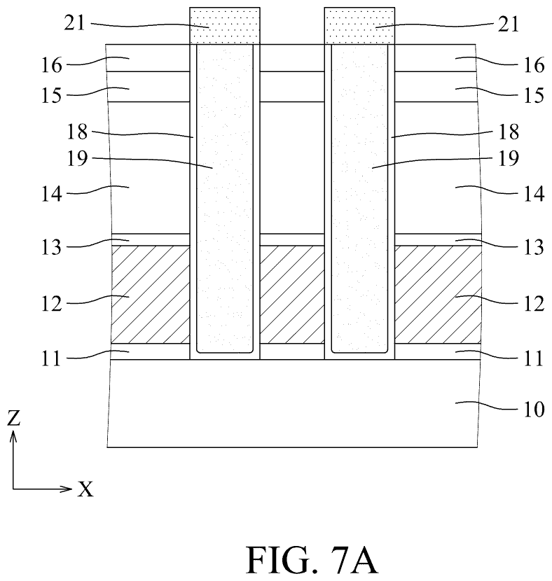

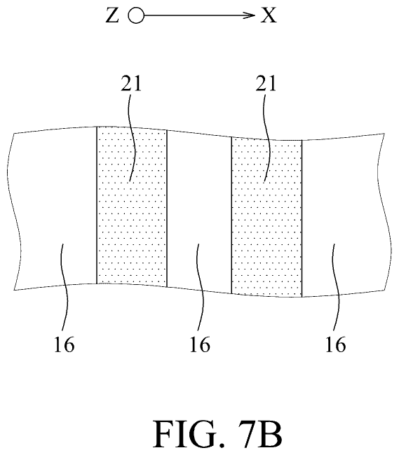

Referring to FIG. 1 and the example illustrated in FIGS. 7A and 7B, the method 100A then proceeds to step S06, where a plurality of mask portions 21 are selectively formed on the dielectric spacers 18 and the dielectric portions 19, followed by removing the blocking portions 20. FIG. 7B illustrates a planar schematic view of the structure shown in FIG. 7A. Each of the mask portions 21 is selectively formed on a corresponding one of the dielectric spacers 18 and a corresponding one of the dielectric portions 19. In some embodiments, the mask portions 21 may include, for example, but not limited to, a conductive material (e.g., metallic material (e.g., metal nitride such as titanium nitride or the like)), a non-conductive material (e.g., dielectric material (e.g., silicon oxide, metal oxide (such as aluminum oxide, hafnium oxide, or the like), metal nitride (e.g., aluminum nitride or the like), or the like)), or a combination thereof. Other suitable conductive materials or non-conductive materials for forming the mask portions 21 are within the contemplated scope of the present disclosure. In some embodiments, the mask portions 21 may be formed by a suitable deposition process, CVD, PVD, or ALD. Other suitable deposition processes for forming the mask portions 21 are within the contemplated scope of the present disclosure.

The mask portions 16, the dielectric portions 15, the dielectric portions 14, and the etch stop layer portions 13 will be etched in subsequent etching processes (e.g., step S09). The mask portions 21 have an etching selectivity smaller than an etching selectivity of the mask portions 16, an etching selectivity of the dielectric portions 15, an etching selectivity of the dielectric portions 14, and an etching selectivity of the etch stop layer portions 13, so that the mask portions 21 remain substantially intact in the subsequent etching processes. In some embodiments, a ratio of each of the etching selectivity of the mask portions 16, the etching selectivity of the dielectric portions 15, the etching selectivity of the dielectric portions 14, and the etching selectivity of the etch stop layer portions 13 to the etching selectivity of the mask portions 21 is greater than 1. The thickness of the mask portions 21 is determined based on etching selectivity difference between the mask portions 21 and the mask portions 16, the dielectric portions 15, the dielectric portions 14, and/or the etch stop layer portions 13, and is also based on a thickness of a stack of one of the mask portions 16, a corresponding one of the dielectric portions 15, a corresponding one of the dielectric portions 14, and a corresponding one of the etch stop layer portions 13. In some embodiments, the thickness of the mask portions 21 may range from about 10 Å to about 5000 Å.

In this step, after the mask portions 21 are formed, the blocking portions 20 are removed by a suitable removal process, for example, but not limited to, a thermal treatment (e.g., baking) or a plasma treatment. Other suitable removal processes for removing the blocking portions 20 are within the contemplated scope of the present disclosure.

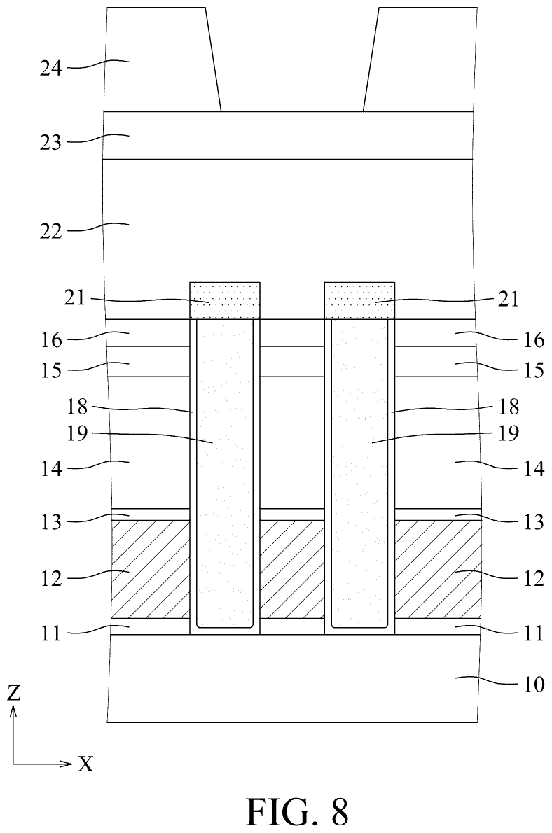

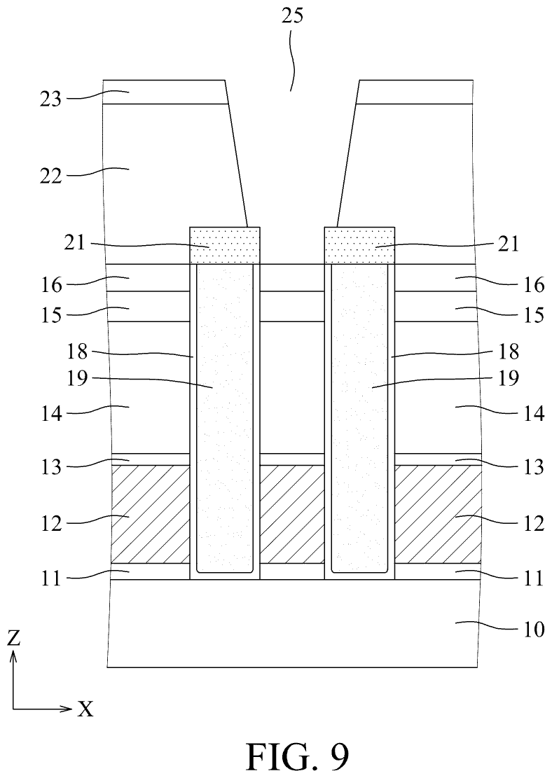

Referring to FIG. 1 and the example illustrated in FIG. 8, the method 100A then proceeds to step S07, where a bottom mask layer 22, a middle mask layer 23, and a patterned photoresist layer 24 are sequentially formed on the structure shown in FIG. 7A. Each of the bottom mask layer 22, the middle mask layer 23, and the patterned photoresist layer 24 has an etching selectivity greater than the etching selectivity of the mask portions 21. In some embodiments, a ratio of the etching selectivity of e ach of the bottom mask layer 22, the middle mask layer 23, and the patterned photoresist layer 24 to the etching selectivity of the mask portions 21 is greater than about 1. Step S07 includes sub-steps (i) to (iii).

In sub-step (i), the bottom mask layer 22 is formed on the structure shown in FIG. 7A. In some embodiments, the bottom mask layer 22 may include a carbon-based polymer. Other suitable materials for forming the bottom mask layer 22 are within the contemplated scope of the present disclosure. In some embodiments, the bottom mask layer 22 may be formed by a suitable deposition process, for example, but not limited to, CVD or spin-on coating. Other suitable deposition processes for forming the bottom mask layer 22 are within the contemplated scope of the present disclosure.

In sub-step (ii), the middle mask layer 23 is formed on the bottom mask layer 22. In some embodiments, the middle mask layer 23 may include, for example, but not limited to, silicon oxide, silicon oxycarbide, silicon oxynitride, silicon oxycarbonitride, or combinations thereof. Other suitable materials for forming the middle mask layer 23 are within the contemplated scope of the present disclosure. In some embodiments, the middle mask layer 23 may be formed by a suitable deposition process, for example, but not limited to, CVD, PVD, or ALD. Other suitable deposition processes for forming the middle mask layer 23 are within the contemplated scope of the present disclosure.

In sub-step (iii), the patterned photoresist layer 24 is formed on the middle mask layer 23 opposite to the bottom mask layer 22. In some embodiments, the material and the process for forming the patterned photoresist layer 24 may be the same as or similar to those for forming the patterned photoresist described above in step S02, and thus details thereof are omitted for the sake of brevity.

Referring to FIG. 1 and the example illustrated in FIG. 9, the method 100A then proceeds to step S08, where a portion of the middle mask layer 23 and a portion of the bottom mask layer 22 are removed, so as to form an opening 25 and to expose a corresponding one of the mask portions 16 from the opening 25. Step S08 may be performed by a suitable etching process, for example, but not limited to, a dry etching process. Other suitable etching processes for removing the portion of the middle mask layer 23 and the portion of the bottom mask layer 22 are within the contemplated scope of the present disclosure. It is noted that after this step, two corresponding ones of the mask portions 21 may be partially exposed from the opening 25. In some embodiments, two or more of the openings 25 may be formed to expose corresponding ones of the mask portions 16 from the openings 25, respectively, and each of the openings 25 permits two corresponding ones of the mask portions 21 to be partially exposed. The patterned photoresist layer 24 is removed gradually during the etching process. As described above, the etching selectivity of each of the bottom mask layer 22, the middle mask layer 23, and the patterned photoresist layer 24 is greater than the etching selectivity of the mask portions 21. Therefore, the mask portions 21 remain substantially intact after the etching process.

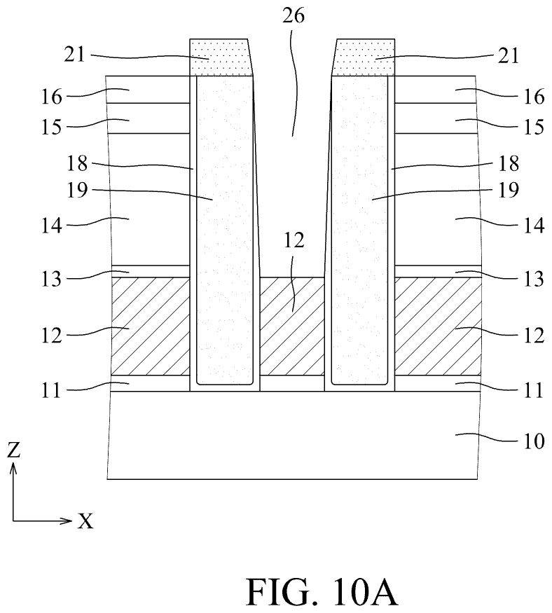

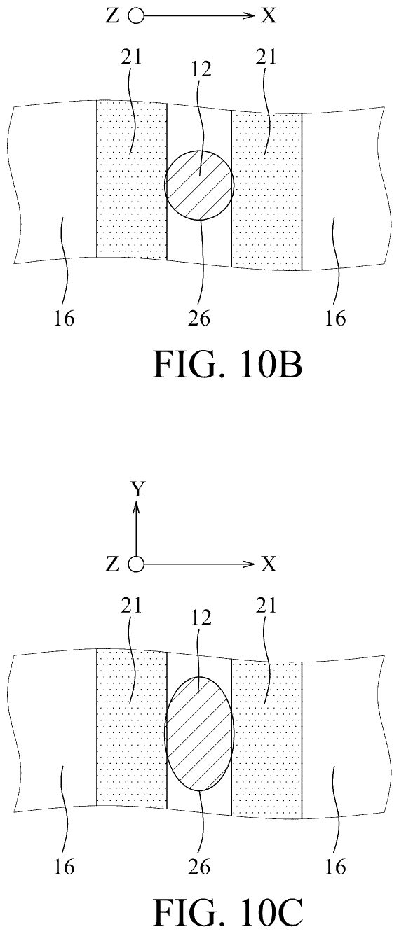

Referring to FIG. 1 and the example illustrated in FIGS. 10A and 10B, the method 100A then proceeds to step S09, where at least one another etching process (for example, but not limited to, a dry etching process or other suitable etching processes) is performed to remove a corresponding one of the mask portions 16, a corresponding one of the dielectric portions 15, a corresponding one of the dielectric portions 14, and a corresponding one of the etch stop layer portions 13 which are disposed below the opening 25 (see FIG. 9), so as to form a via opening 26. FIG. 10B illustrates a planar schematic view of the structure shown in FIG. 10A. The via opening 26 exposes a corresponding one of the metal lines 12. In some embodiments, two or more of the via openings 26 may be formed to expose corresponding ones of the metal lines 12, respectively. In some embodiments, the at least one another etching process may be an inductively coupled plasma (ICP) etching process or a capacitively coupled plasma (CCP) etching process. In some embodiments, a source gas used in the ICP etching process or the CCP etching process may include, for example, but not limited to, hydrogen bromide gas, chlorine gas, hydrogen gas, methane gas, nitrogen gas, helium gas, neon gas, krypton gas, tetrafluoromethane gas, fluoroform gas, fluoromethane gas, difluoromethane gas, octafluorocyclobutane gas, hexafluorobutadiene gas, sulfur hexafluoride gas, oxygen gas, argon gas, or combinations thereof. Other suitable source gases used in the ICP etching process or the CCP etching process are within the contemplated scope of the present disclosure. In some embodiments, the plasma generation power used in the ICP etching process or the CCP etching process may range from about 100 W to about 2000 W. In some embodiments, the plasma bias used in the ICP etching process or the CCP etching process may range from about 0 W to about 1200 W. As described above, the etching selectivity of each of the bottom mask layer 22 and the middle mask layer 23 is greater than the etching selectivity of the mask portions 21. The middle mask layer 23 and the bottom mask layer 22 which remain after step S08 may be fully etched away after this step. In some alternative embodiments, if the middle mask layer 23 and the bottom mask layer 22 still remain and are not fully etched away after this step, an additional removal process may be performed to fully remove the middle mask layer 23 and the bottom mask layer 22.

As described above, the etching selectivity of the mask portions 21 is smaller than the etching selectivity of the mask portions 16, the etching selectivity of the dielectric portions 15, the etching selectivity of the dielectric portions 14, and the etching selectivity of the etch stop layer portions 13. Therefore, the mask portions 21 may remain substantially intact or may be slightly etched away (as shown in FIG. 10A) only after step S09.

As described above, in some embodiments, the thickness of the mask portions 21 may range from about 10 Å to about 5000 Å. If the thickness of the mask portions 21 is smaller than about 10 Å, the mask portions 21 may not provide an effective masking function in the at least one another etching process performed in step S09. If the thickness of the mask portions 21 is greater than about 5000 Å, production cost for removal of the mask portions 21 in a subsequent process (e.g., step S11) may be increased.

In some embodiments, the via opening 26 has a circular shape as shown in FIG. 10B. In some embodiments, as shown in FIG. 10C, the via opening 26 has an elliptical shape, in which a dimension of the via opening 26 in a Y direction transverse to the X direction and the Z direction is greater than a dimension of the via opening 26 in the X direction. Other geometrical shapes for the via opening 26 are within the contemplated scope of the present disclosure. In some embodiments, the geometrical shape or size of the via opening 26 may be adjusted by an optical proximity correction (OPC) technique during formation thereof.

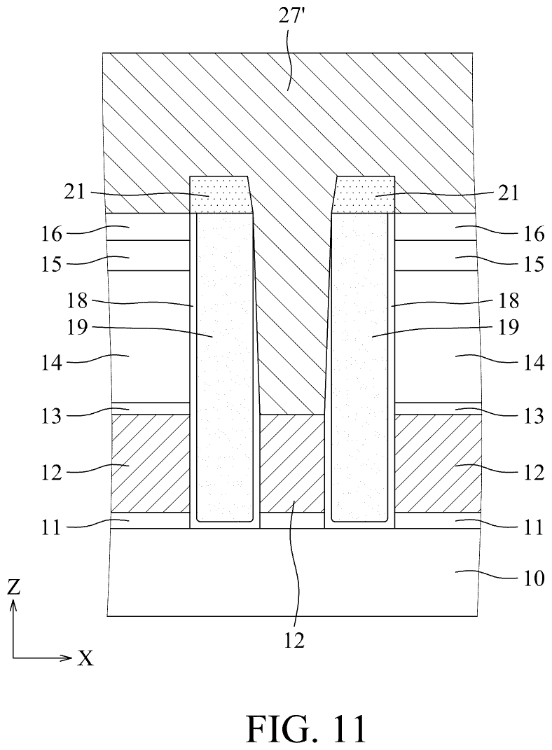

Referring to FIG. 1 and the example illustrated in FIG. 11, the method 100A then proceeds to step S10, where a contact via material layer 27′ is formed on the structure shown in FIG. 10A and fills the via opening 26. In some embodiments, the contact via material layer 27′ may include, for example, but not limited to, copper, molybdenum, ruthenium, cobalt, tantalum, niobium, aluminum, or combinations thereof. Other suitable materials for forming the contact via material layer 27′ are within the contemplated scope of the present disclosure. In some embodiments, the contact via material layer 27′ may be formed by a suitable deposition process, for example, but not limited to, CVD or PVD. Other suitable deposition processes for forming the contact via material layer 27′ are within the contemplated scope of the present disclosure.

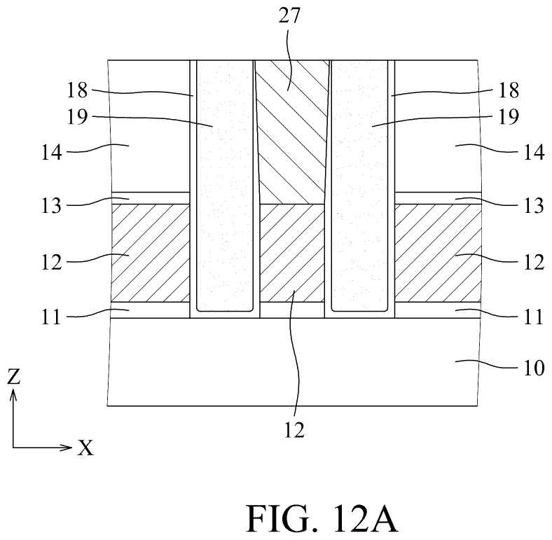

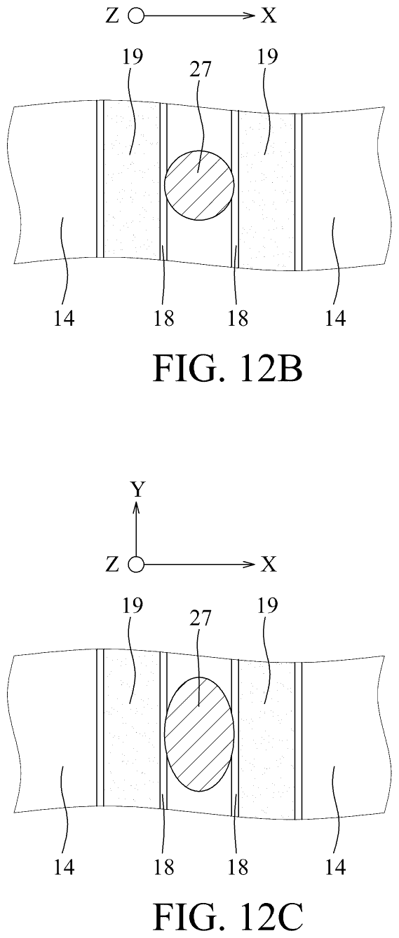

Referring to FIG. 1 and the example illustrated in FIGS. 12A and 12B, the method 100A then proceeds to step S11, where a planarization process is performed on the structure shown in FIG. 11. FIG. 12B illustrates a planar schematic view of the structure shown in FIG. 12A. In some embodiments, the planarization process may be, for example, but not limited to, CMP. Other suitable planarization processes are within the contemplated scope of the present disclosure. After this step, a portion of the contact via material layer 27′, the mask portions 21, a portion of each of the dielectric portions 19, a portion of each of the dielectric spacers 18, the mask portions 16, the dielectric portions 15, and a portion of each of the dielectric portions 14 are removed. In some embodiments, remainder of the contact via material layer 27′ is formed into a contact via 27. In some embodiments, two or more of the contact vias 27 may be formed in this step. In some embodiments, the contact via 27 is disposed on and electrically connected to a corresponding one of the metal lines 12. In some embodiments in which the via opening 26 has a circular shape (see FIG. 10B), the contact via 27 thus formed has a circular shape as shown in FIG. 12B. In some embodiments in which the via opening 26 has an elliptical shape (see FIG. 10C), the contact via 27 thus formed has an elliptical shape as shown in FIG. 12C, so that a contact area between the contact via 27 and a corresponding one of the metal lines 12 may be increased, which is conducive to reducing a contact resistance between the contact via 27 and the corresponding one of the metal lines 12. Other geometrical shapes for the contact via 27 are within the contemplated scope of the present disclosure. In some embodiments, the contact via 27 may have a thickness ranging from about 100 Å to about 5000 Å.

Referring to FIG. 1 and the example illustrated in FIG. 13, the method 100A then proceeds to step S12, where an etch stop layer 28, a dielectric layer 29, and a plurality of metal lines 30 are sequentially formed. One of the metal lines 30 is shown in FIG. 13. Step S12 may include sub-steps (i) to (iii).

In sub-step (i), the etch stop layer 28 is formed on the structure shown in FIG. 12A. The material and the process for forming the etch stop layer 28 may be the same as or similar to those for forming the etch stop layer 13′, and thus details thereof are omitted for the sake of brevity. In some embodiments, the etch stop layer 28 may be not formed.

In sub-step (ii), the dielectric layer 29 is formed on the etch stop layer 28 opposite to the interconnect structure 10. The material and the process for forming the dielectric layer 29 may be the same as or similar to those for forming the dielectric layer 14′, and thus details thereof are omitted for the sake of brevity.

In sub-step (iii), the metal lines 30 are formed in the etch stop layer 28 and the dielectric layer 29. In this sub-step, a patterning process (e.g., a photolithography process (as described in step S02) or other suitable patterning processes) is performed on the structure obtained after sub-step (ii) to form a plurality of trenches (not shown), followed by depositing a metal line material (not shown) to fill the trenches and removing an excess portion of the thus formed metal line material layer over the dielectric layer 29 by a planarization process (e.g., CMP or other suitable planarization processes), so as to obtain the metal lines 30. The contact via 27 is disposed below and electrically connected to a corresponding one of the metal lines 30. In some embodiments, each of the metal lines 30 may have a thickness ranging from about 100 Å to about 5000 Å.

After step S12, the semiconductor device 200A is obtained. In the formation of the semiconductor device 200A, by having the mask portions 21 respectively disposed on the dielectric portions 19 and the dielectric spacers 18, the contact via 27 can be precisely formed on a corresponding one of the metal lines 12, so as to prevent a mismatch between the contact via 27 and the corresponding one of the metal lines 12, thereby preventing a current leakage between the contact via 27 and another metal line that is adjacent to the corresponding one of the metal lines 12 and degradation in the TDDB.

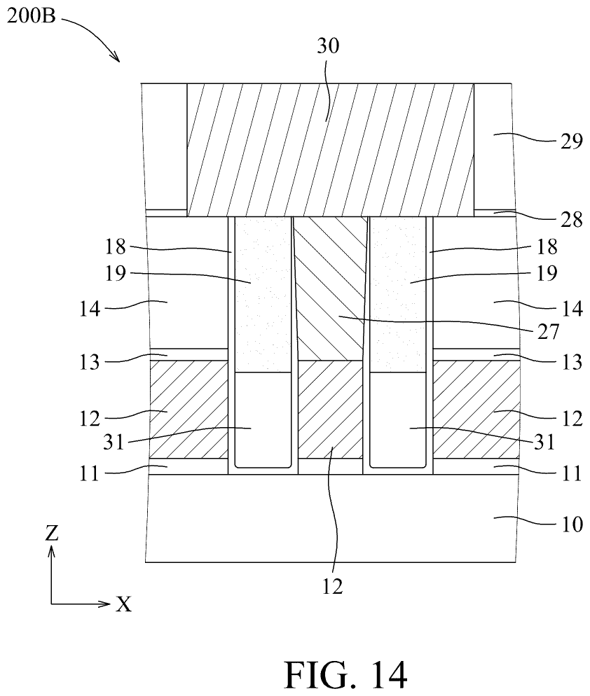

FIG. 14 illustrates a schematic view of a semiconductor device 200B in accordance with some embodiments. The structure of the semiconductor device 200B is similar to that of the semiconductor device 200A, except that, the semiconductor device 200B further includes a plurality of air gaps 31, each of which is disposed between two adjacent ones of the metal lines 12. A method for manufacturing the semiconductor device 200B is similar to the method 100A except for step S03.

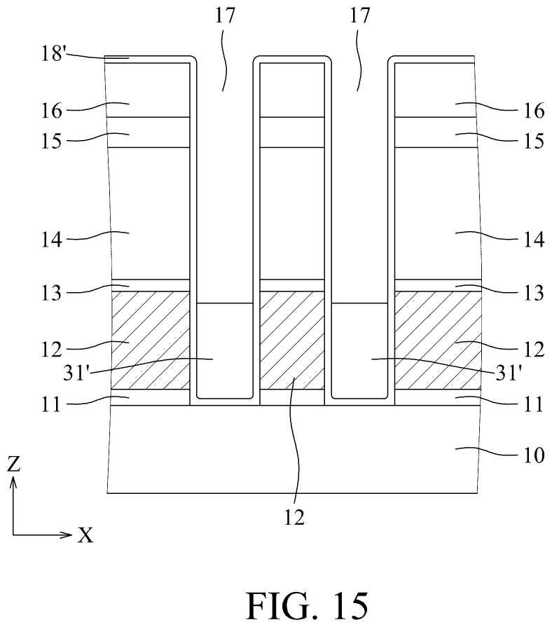

FIG. 15 illustrates that, in step S03, after formation of the dielectric spacer layer 18′ and before formation of the dielectric layer 19′, a plurality of sacrificial portions 31′ are formed in the trenches 17, respectively. In some embodiments, the sacrificial portions 31′ may be formed by depositing a sacrificial material (not shown) on the dielectric spacer layer 18′ to fill the trenches 17, followed by removing an excess portion of the thus formed sacrificial material layer. In some embodiments, the sacrificial material layer may include, for example, but not limited to, silicon oxide, silicon nitride, silicon carbide, silicon carbon nitride, silicon oxycarbide, aluminum oxide, aluminum nitride, aluminum oxynitride, or combinations thereof. Other suitable materials for forming the sacrificial material layer are within the contemplated scope of the present disclosure. In some embodiments, the sacrificial material layer may be formed by a suitable deposition process, for example, but not limited to, CVD, PVD, or ALD. Other suitable deposition processes for forming the sacrificial material layer are within the contemplated scope of the present disclosure. In some embodiments, an upper surface of each of the sacrificial portions 31′ may be not higher than that of each of the metal lines 12. In some embodiments, each of the sacrificial portions 31′ may have a thickness ranging from about 10 Å to about 5000 Å. If the thickness of the sacrificial portions 31′ is greater than about 5000 Å, the via opening 26 thus formed in a subsequent process (i.e., step S09) may extend through a corresponding one of the dielectric spacers 18 and a corresponding one of the dielectric portions 19 to be in spatial communication with a corresponding one of the air gaps 31 that is formed by removing the sacrificial portions 31′, which may adversely affect formation of the contact via 27 (i.e., steps S10 and S11).

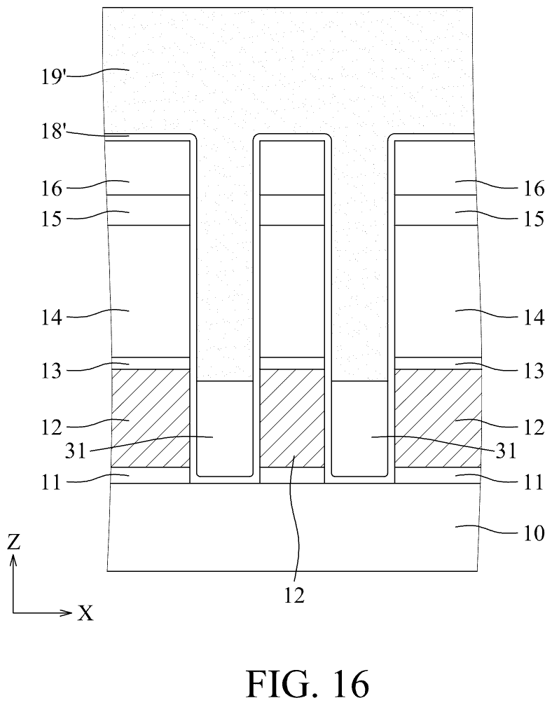

FIG. 16 illustrates that, after formation of the sacrificial portions 31′, the dielectric layer 19′ is formed on the structure shown in FIG. 15, followed by removing the sacrificial portions 31′, so as to obtain the air gaps 31. In some embodiments, the sacrificial portions 31′ may be removed by a thermal treatment, so that materials of the sacrificial portions 31′ diffuse through the dielectric layer 19′ which has a porous structure. In some embodiments, the thermal treatment may be, for example, but not limited to, an annealing treatment, an ultraviolet curing treatment, or a combination thereof. In some embodiments, the annealing treatment may include, for example, but not limited to, thermal annealing, flash lamp annealing, or laser annealing. In some embodiments, the annealing treatment may be performed at a temperature ranging from about 50° C. to about 400° C. If the temperature of the annealing treatment is lower than about 50° C., the time period for performing the thermal treatment to remove the sacrificial portions 31′ may be increased. If the temperature of the annealing treatment is larger than about 400° C., some defects may be formed in the semiconductor device 200B. Other suitable removal processes for removing the sacrificial portions 31′ are within the contemplated scope of the present disclosure.

In some embodiments, after the formation of the sacrificial portions 31′, a portion of the dielectric layer 19′ is formed on the sacrificial portions 31′ in the trenches 17, followed by sequentially removing the sacrificial portions 31′ through the portion of the dielectric layer 19', and then forming a remaining portion of the dielectric layer 19′ to fill the trenches 17.

In the semiconductor device 200B, by having the air gaps 31, which have a dielectric constant of 1, the capacitance between the metal lines 12 may be decreased, which is conducive to enhancing device performance of the semiconductor device 200B.

In a method for manufacturing a semiconductor device of this disclosure, by selectively and respectively forming mask portions on dielectric portions, an contact via can be precisely formed between two adjacent ones of the dielectric portions and on a corresponding one of metal lines, which is conducive to preventing current leakage and degradation in TDDB in the semiconductor device. In addition, by forming an air gap between two adjacent ones of the metal lines, a capacitance between the two adjacent ones of the metal lines can be reduced, which is advantageous for lowering a resistance-capacitance (RC) time delay of a circuit structure in the semiconductor device. Therefore, device performance, production yield, and reliability of the semiconductor device of this disclosure can be enhanced.

In accordance with some embodiments of the present disclosure, a method for manufacturing a semiconductor device includes: forming a plurality of metal lines on a substrate, the plurality of metal lines being spaced apart from one another; forming a plurality of first dielectric portions on the plurality of metal lines, respectively; forming a plurality of first mask portions on the plurality of first dielectric portions, respectively; forming a plurality of second dielectric portions on the substrate, so that two adjacent ones of the plurality of second dielectric portions are spaced apart from one another by a corresponding one of the plurality of first dielectric portions and a corresponding one of the plurality of metal lines; selectively forming a plurality of second mask portions on the plurality of second dielectric portions, respectively; removing one of the plurality of first mask portions and a corresponding one of the plurality of first dielectric portions, so as to form an opening that exposes a corresponding one of the plurality of metal lines; forming a contact via material layer to fill the opening; and removing a portion of the contact via material layer, remaining ones of the plurality of first mask portions and the plurality of second mask portions, so as to form a contact via that is disposed on and electrically connected to the corresponding one of the plurality of metal lines.

In accordance with some embodiments of the present disclosure, the plurality of first mask portions include a metallic material.

In accordance with some embodiments of the present disclosure, the plurality of second mask portions include a conductive material or a non-conductive material.

In accordance with some embodiments of the present disclosure, the conductive material includes conductive metal nitride.

In accordance with some embodiments of the present disclosure, the non-conductive material includes silicon oxide, dielectric metal oxide, dielectric metal nitride, or combinations thereof.

In accordance with some embodiments of the present disclosure, each of the plurality of second mask portions has a thickness ranging from about 10 Å to about 5000 Å.

In accordance with some embodiments of the present disclosure, an etching selectivity of the plurality of first mask portions and an etching selectivity of the plurality of first dielectric portions are greater than an etching selectivity of the plurality of second mask portions.

In accordance with some embodiments of the present disclosure, a method for manufacturing a semiconductor device includes: forming a plurality of metal lines on a substrate, the plurality of metal lines being spaced apart from one another; forming a plurality of first dielectric portions on the plurality of metal lines, respectively; forming a plurality of first mask portions on the plurality of first dielectric portions, respectively; forming a plurality of second dielectric portions on the substrate, so that two adjacent ones of the plurality of second dielectric portions are spaced apart from one another by a corresponding one of the plurality of first dielectric portions and a corresponding one of the plurality of metal lines; selectively and respectively forming a plurality of blocking portions on the plurality of first mask portions to expose the plurality of second dielectric portions; selectively forming a plurality of second mask portions on the plurality of second dielectric portions, respectively; removing the plurality of blocking portions; removing one of the plurality of first mask portions and a corresponding one of the plurality of first dielectric portions, so as to form an opening that exposes a corresponding one of the plurality of metal lines; forming a contact via material layer to fill the opening; and removing a portion of the contact via material layer, remaining ones of the plurality of first mask portions and the plurality of second mask portions, so as to form a contact via that is disposed on and electrically connected to the corresponding one of the plurality of metal lines.

In accordance with some embodiments of the present disclosure, the plurality of first dielectric portions and the plurality of second dielectric portions are made of different materials.

In accordance with some embodiments of the present disclosure, the plurality of blocking portions are made from a self-assembled monolayer material that includes an organic molecule, a polymer, or a combination thereof.

In accordance with some embodiments of the present disclosure, the method for manufacturing the semiconductor device further includes: after formation of the plurality of second mask portions and before formation of the opening, forming a mask structure on the plurality of first mask portions and the plurality of second mask portions, the opening being formed by removing a portion of the mask structure, the one of the plurality of first mask portions and the corresponding one of the plurality of first dielectric portions.

In accordance with some embodiments of the present disclosure, the mask structure includes a bottom mask layer and a middle mask layer disposed on the bottom mask layer, the bottom mask layer and the middle mask layer being made of different materials.

In accordance with some embodiments of the present disclosure, an etching selectivity of each of the bottom mask layer and the middle mask layer is greater than an etching selectivity of the plurality of second mask portions.

In accordance with some embodiments of the present disclosure, a method for manufacturing a semiconductor device includes: forming a metal line material layer on a substrate; forming a dielectric layer on the metal line material layer opposite to the substrate; forming a mask layer on the dielectric layer opposite to the metal line material layer; forming a plurality of trenches that are spaced apart from each other and that penetrate the mask layer, the dielectric layer and the metal line material layer to terminate at an upper surface of the substrate, so that the metal line material layer is formed into a plurality of metal lines, the dielectric layer is formed into a plurality of first dielectric portions, and the mask layer is formed into a plurality of first mask portions; forming a plurality of second dielectric portions to fill the plurality of trenches, respectively; selectively forming a plurality of second mask portions on the plurality of second dielectric portions, respectively; removing one of the plurality of first mask portions and a corresponding one of the plurality of first dielectric portions, so as to form an opening that exposes a corresponding one of the plurality of metal lines; forming a contact via material layer to fill the opening; and removing a portion of the contact via material layer, remaining ones of the plurality of first mask portions and the plurality of second mask portions, so as to form a contact via that is disposed on and electrically connected to the corresponding one of the plurality of metal lines.

In accordance with some embodiments of the present disclosure, the plurality of second mask portions include titanium nitride, silicon oxide, aluminum oxide, hafnium oxide, or aluminum nitride.

In accordance with some embodiments of the present disclosure, the method for manufacturing the semiconductor device further includes a plurality of air gaps below the plurality of second dielectric portions, respectively, so that two corresponding ones of the plurality of metal lines are spaced apart from each other by a corresponding one of the plurality of air gaps.

In accordance with some embodiments of the present disclosure, formation of the plurality of air gaps includes: before formation of the plurality of second dielectric portions, forming a plurality of sacrificial portions in the plurality of trenches, respectively, forming the plurality of second dielectric portions on the plurality of sacrificial portions, respectively, and removing the plurality of sacrificial portions, so as to form the plurality of air gaps.

In accordance with some embodiments of the present disclosure, the plurality of sacrificial portions include silicon oxide, silicon nitride, silicon carbide, silicon carbon nitride, silicon oxycarbide, aluminum oxide, aluminum nitride, aluminum oxynitride, or combinations thereof.

In accordance with some embodiments of the present disclosure, each of the plurality of sacrificial portions has a thickness ranging from about 10 Å to about 5000 Å.

In accordance with some embodiments of the present disclosure, each of the plurality of sacrificial portions is located at a level that is not higher than a level of each of the plurality of metal lines.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a plurality of metal lines on a substrate, the plurality of metal lines being spaced apart from one another;
forming a plurality of first dielectric portions on the plurality of metal lines, respectively;
forming a plurality of first mask portions on the plurality of first dielectric portions, respectively;
forming a plurality of second dielectric portions on the substrate, so that two adjacent ones of the plurality of second dielectric portions are spaced apart from one another by a corresponding one of the plurality of first dielectric portions and a corresponding one of the plurality of metal lines;
selectively forming a plurality of second mask portions on the plurality of second dielectric portions, respectively;
removing one of the plurality of first mask portions and a corresponding one of the plurality of first dielectric portions, so as to form an opening that exposes a corresponding one of the plurality of metal lines;
forming a contact via material layer to fill the opening; and
removing a portion of the contact via material layer, remaining ones of the plurality of first mask portions and the plurality of second mask portions, so as to form a contact via that is disposed on and electrically connected to the corresponding one of the plurality of metal lines.

2. The method as claimed in claim 1, wherein the plurality of first mask portions include a metallic material.

3. The method as claimed in claim 1, wherein the plurality of second mask portions include a conductive material or a non-conductive material.

4. The method as claimed in claim 3, wherein the conductive material includes conductive metal nitride.

5. The method as claimed in claim 3, wherein the non-conductive material includes silicon oxide, dielectric metal oxide, dielectric metal nitride, or combinations thereof.

6. The method as claimed in claim 1, wherein each of the plurality of second mask portions has a thickness ranging from 10 Å to 5000 Å.

7. The method as claimed in claim 1, wherein an etching selectivity of the plurality of first mask portions and an etching selectivity of the plurality of first dielectric portions are greater than an etching selectivity of the plurality of second mask portions.

8. A method for manufacturing a semiconductor device, comprising:
forming a plurality of metal lines on a substrate, the plurality of metal lines being spaced apart from one another;
forming a plurality of first dielectric portions on the plurality of metal lines, respectively;
forming a plurality of first mask portions on the plurality of first dielectric portions, respectively;
forming a plurality of second dielectric portions on the substrate, so that two adjacent ones of the plurality of second dielectric portions are spaced apart from one another by a corresponding one of the plurality of first dielectric portions and a corresponding one of the plurality of metal lines;
selectively and respectively forming a plurality of blocking portions on the plurality of first mask portions to expose the plurality of second dielectric portions;
selectively forming a plurality of second mask portions on the plurality of second dielectric portions, respectively;
removing the plurality of blocking portions;
removing one of the plurality of first mask portions and a corresponding one of the plurality of first dielectric portions, so as to form an opening that exposes a corresponding one of the plurality of metal lines;
forming a contact via material layer to fill the opening; and
removing a portion of the contact via material layer, remaining ones of the plurality of first mask portions and the plurality of second mask portions, so as to form a contact via that is disposed on and electrically connected to the corresponding one of the plurality of metal lines.

9. The method as claimed in claim 8, wherein the plurality of first dielectric portions and the plurality of second dielectric portions are made of different materials.

10. The method as claimed in claim 8, wherein the plurality of blocking portions are made from a self-assembled monolayer material that includes an organic molecule, a polymer, or a combination thereof.

11. The method as claimed in claim 8, further comprising, after formation of the plurality of second mask portions and before formation of the opening, forming a mask structure on the plurality of first mask portions and the plurality of second mask portions, the opening being formed by removing a portion of the mask structure, the one of the plurality of first mask portions and the corresponding one of the plurality of first dielectric portions.

12. The method as claimed in claim 11, wherein the mask structure includes a bottom mask layer and a middle mask layer disposed on the bottom mask layer, the bottom mask layer and the middle mask layer being made of different materials.

13. The method as claimed in claim 12, wherein an etching selectivity of each of the bottom mask layer and the middle mask layer is greater than an etching selectivity of the plurality of second mask portions.

14. A method for manufacturing a semiconductor device, comprising:
forming a metal line material layer on a substrate;
forming a dielectric layer on the metal line material layer opposite to the substrate;
forming a mask layer on the dielectric layer opposite to the metal line material layer ;
forming a plurality of trenches that are spaced apart from each other and that penetrate the mask layer, the dielectric layer and the metal line material layer to terminate at an upper surface of the substrate, so that the metal line material layer is formed into a plurality of metal lines, the dielectric layer is formed into a plurality of first dielectric portions, and the mask layer is formed into a plurality of first mask portions;
forming a plurality of second dielectric portions to fill the plurality of trenches, respectively;
selectively forming a plurality of second mask portions on the plurality of second dielectric portions, respectively;
removing one of the plurality of first mask portions and a corresponding one of the plurality of first dielectric portions, so as to form an opening that exposes a corresponding one of the plurality of metal lines;
forming a contact via material layer to fill the opening; and
removing a portion of the contact via material layer, remaining ones of the plurality of first mask portions and the plurality of second mask portions, so as to form a contact via that is disposed on and electrically connected to the corresponding one of the plurality of metal lines.

15. The method as claimed in claim 14, wherein the plurality of second mask portions include titanium nitride, silicon oxide, aluminum oxide, hafnium oxide, or aluminum nitride.

16. The method as claimed in claim 14, further comprising forming a plurality of air gaps below the plurality of second dielectric portions, respectively, so that two corresponding ones of the plurality of metal lines are spaced apart from each other by a corresponding one of the plurality of air gaps.

17. The method as claimed in claim 16, wherein formation of the plurality of air gaps includes:
before formation of the plurality of second dielectric portions, forming a plurality of sacrificial portions in the plurality of trenches, respectively,
forming the plurality of second dielectric portions on the plurality of sacrificial portions, respectively, and
removing the plurality of sacrificial portions, so as to form the plurality of air gaps.

18. The method as claimed in claim 17, wherein the plurality of sacrificial portions include silicon oxide, silicon nitride, silicon carbide, silicon carbon nitride, silicon oxycarbide, aluminum oxide, aluminum nitride, aluminum oxynitride, or combinations thereof.

19. The method as claimed in claim 17, wherein each of the plurality of sacrificial portions has a thickness ranging from 10 Å to 5000 Å.

20. The method as claimed in claim 17, wherein each of the plurality of sacrificial portions is located at a level that is not higher than a level of each of the plurality of metal lines.
